(19) United States
(12) Patent Application Publication
(10) Pub. No.: US 2026/0367024 A1
(43) Pub. Date: Nov. 19, 2026

(54) SENSOR SIGNAL PROCESSING DEVICE

(71) Applicant: MITSUI CHEMICALS, INC., Chuo-ku, Tokyo (JP)

(72) Inventors: Kenji YOSHIOKA, Chuo-ku, Tokyo (JP); Kei MIYAZAKI, Chuo-ku, Tokyo (JP)

(73) Assignee: MITSUI CHEMICALS, INC., Chuo-ku, Tokyo (JP)

(21) Appl. No.: 19/135,732

(22) PCT Filed: Nov. 16, 2023
(86) PCT No.: PCT/JP2023/041358

§ 371 Date: Jun. 4, 2025

(30) Foreign Application Priority Data
Dec. 6, 2022 (JP) 2022-194906

(51) Int. Cl. G01N 27/04; H03F 3/45

(52) U.S. Cl. CPC G01N 27/045; H03F 3/45475

(57) ABSTRACT

A sensor signal processing device includes a differential amplifier circuit that outputs an output signal according to a difference between a sensor signal output from a sensor and a reference voltage signal, and a control circuit that controls a level of the reference voltage signal on the basis of the sensor signal.

### DESCRIPTION

### Technical Field

The disclosed technology relates to a sensor signal processing device that processes a sensor signal output from a sensor

### Background Art

As a technique related to a sensor signal processing device that processes a sensor signal output from a sensor, the following technique is known. For example, Japanese Patent Application Laid-Open (JP-A) No. 2007-208427 discloses a sensor module offset cancellation circuit including a strain sensor, a plurality of operational amplifiers, a controller that controls an AD/DA converter, an RFIC connected to the controller, and an antenna connected to the RFIC.

### SUMMARY OF INVENTION

### Technical Problem

A sensor signal output from a sensor is amplified by an amplifier circuit since a normal signal level is minute. A reference level (zero level) of the sensor signal may change due to aging or the like. In a case in which the reference level of the sensor signal changes, since the change is also amplified by the amplifier circuit, an output signal of the amplifier circuit exceeds a dynamic range, and the output signal of the amplifier circuit may be distorted.

In order to cancel the variation in a reference level of a sensor signal, for example, as disclosed in JP-A-2007-208427, an aspect of performing feedback control on the basis of an output signal of an amplifier circuit is considered. However, in this case, in order to derive a control amount for canceling the variation in the reference level of the sensor signal, it is necessary to take into account an amplification factor of the amplifier circuit, and the design is not easy. In a case in which the output signal of the amplifier circuit exceeds the dynamic range, adjustment becomes difficult. It is necessary to provide a calibration mode separately from a normal operation mode in order to derive the control amount for canceling the variation in the reference level of the sensor signal. In the calibration mode, sensing of the sensor cannot be continued.

The disclosed technology has been made in view of the above points, and an object thereof is to cancel a variation in a reference level of a sensor signal without depending on an amplification factor of an amplifier circuit and without providing a calibration mode in a sensor signal processing device including the amplifier circuit.

### Solution to Problem

A sensor signal processing device according to the disclosed technology includes: a differential amplifier circuit that outputs an output signal according to a difference between a sensor signal output from a sensor and a reference voltage signal; and a control circuit that controls a level of the reference voltage signal on the basis of the sensor signal.

The control circuit may increase or decrease the level of the reference voltage signal by an amount corresponding to a change amount of a reference level of the sensor signal. The control circuit may adjust the level of the reference voltage signal on the basis of a low-frequency component of the sensor signal. The sensor signal processing device may further include a low-pass filter that extracts a low-frequency component of the sensor signal. The control circuit may adjust the level of the reference voltage signal on the basis of an average value of sampling values of the sensor signal.

The differential amplifier circuit may have two input terminals. The sensor signal may be input to one of the input terminals, and the reference voltage signal may be input to the other of the input terminals.

The sensor signal processing device may further include an analog-to-digital converter that converts the sensor signal into a digital signal.

The sensor signal processing device may further include the sensor. The sensor may include a resistive element of which a resistance value changes according to a concentration of a gas containing a specific component, and output a signal at a level according to the resistance value of the resistive element as the sensor signal.

### Advantageous Effects of Invention

According to the disclosed technology, in the sensor signal processing device including the amplifier circuit, the variation in the reference level of the sensor signal can be canceled without depending on the amplification factor of the amplifier circuit and without providing the calibration mode.

### BRIEF DESCRIPTION OF DRAWINGS

FIG. 1 is a diagram showing an example of a configuration of a sensor signal processing device 10 according to an embodiment of the disclosed technology.

FIG. 2A is a plan view showing an example of a configuration of a MEMS element according to the embodiment of the disclosed technology.

FIG. 2B is a plan view showing an example of a configuration of the MEMS element according to the embodiment of the disclosed technology.

FIG. 3 is a signal waveform diagram showing an example of a sensor signal according to the embodiment of the disclosed technology.

FIG. 4 is a signal waveform diagram showing an example of an output signal of a differential amplifier circuit 30 of the disclosed technology.

FIG. 5 is a signal waveform diagram showing an example of a sensor signal according to an embodiment of the disclosed technology.

FIG. 6A is a diagram showing an example of input/output waveforms of the differential amplifier circuit in a case in which level control of a reference voltage signal is not performed by a control circuit according to an embodiment of the disclosed technology.

FIG. 6B is a diagram showing an example of input/output waveforms of the differential amplifier circuit in a case in which the level control of the reference voltage signal is not performed by the control circuit according to the embodiment of the disclosed technology.

FIG. 6C is a diagram showing an example of input/output waveforms of the differential amplifier circuit in a case in which the level control of the reference voltage signal is not performed by the control circuit according to the embodiment of the disclosed technology.

### DESCRIPTION OF EMBODIMENTS

Hereinafter, an example of an embodiment of the disclosed technology will be described with reference to the drawings. In the drawings, the same or equivalent constituents and portions are denoted by the same reference numerals, and redundant description will be omitted.

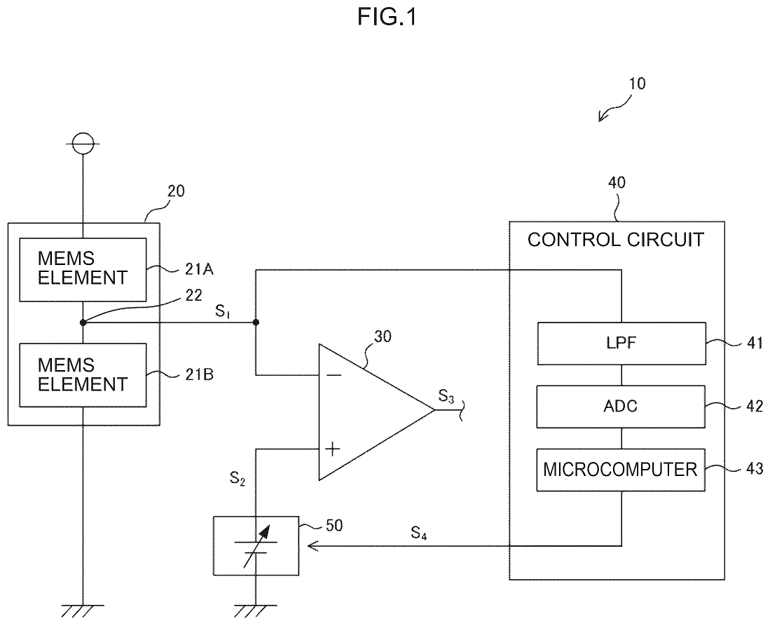

FIG. 1 is a diagram showing an example of a configuration of a sensor signal processing device 10 according to an embodiment of the disclosed technology. The sensor signal processing device 10 includes a sensor 20, a differential amplifier circuit 30, a control circuit 40, and a voltage output circuit 50.

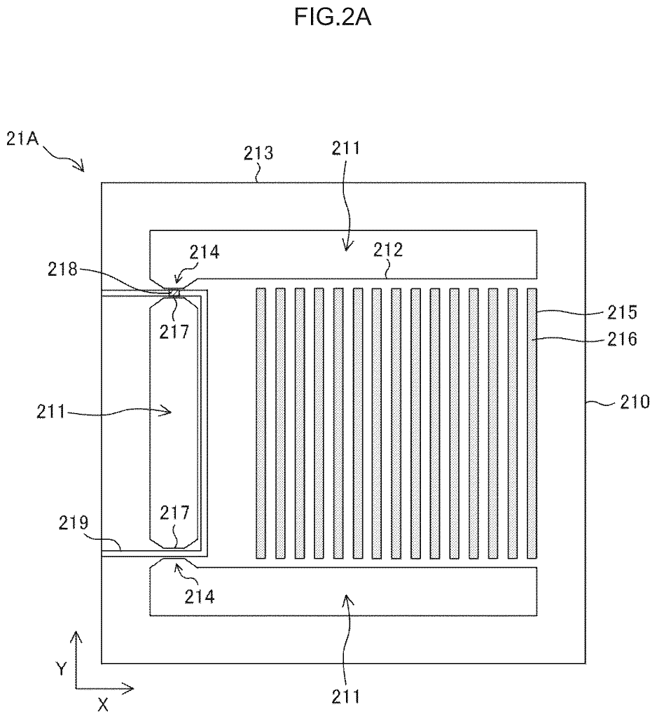

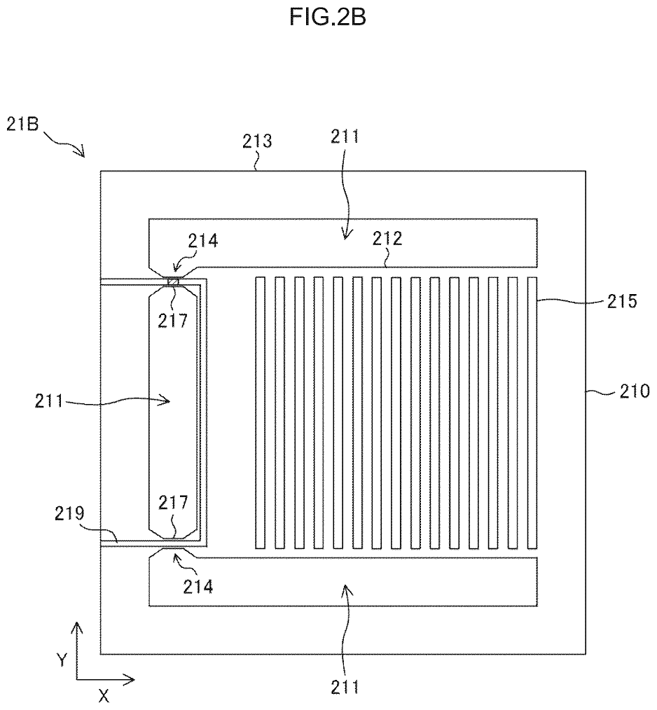

In the present embodiment, the sensor 20 is a gas sensor that outputs a sensor signal Si corresponding to the concentration of a gas containing a specific component. The sensor 20 includes two micro electro mechanical systems (MEMS) elements 21A and 21B. FIG. 2A is a plan view showing an example of a configuration of the MEMS element 21A, and FIG. 2B is a plan view showing an example of a configuration of the MEMS element 21B.

The MEMS elements 21A and 21B have a flat plate member 210 made of, for example, silicon. The flat plate member 210 has three through-holes 211. The flat plate member 210 is provided with a main body portion 212 defined by the three through-holes 211, a frame portion 213, and a connection portion 214. The main body portion 212 is connected to the frame portion 213 via connection portions 214 at two locations at one end in the X direction. The main body portion 212 has a plurality of slits 215 extending in the Y direction. The plurality of slits 215 are arranged in the X direction. In the MEMS element 21A, the plurality of slits 215 are filled with a polymer 216 of which a volume changes due to adsorption of a specific component contained in a gas. However, in the MEMS clement 21B, the plurality of slits 215 are not filled with the polymer.

Each of the connection portions 214 has a narrow portion 217 having a partially narrow width on a path from the main body portion 212 to the frame portion 213. A piezoresistive element 218 is provided on the narrow portion 217 of one of the connection portions 214 provided at two locations. The piezoresistive element 218 is an element to which a piezoresistive effect in which an electric resistance value changes with pressure is applied. A wiring 219 is connected to both ends of the piezoresistive element 218. The wiring 219 extends to the ends of the MEMS elements 21A and 21B, and thus a resistance value of the piezoresistive element 218 can be monitored from the outside.

In the MEMS element 21A, in a case in which a specific component contained in the gas is adsorbed by the polymer 216 filled into the slit 215, the volume of the polymer 216 changes, and the main body portion 212 expands or contracts. As a result, stress is applied to the piezoresistive element 218 provided in the narrow portion 217, and a resistance value changes. The amount of change in the resistance value is an amount corresponding to the concentration of a specific component contained in the gas. In the MEMS element 21B, since the slit 215 is not filled with the polymer 216, a resistance value does not change according to the specific component contained in the gas. Details of the MEMS elements 21A and 21B are disclosed in WO 2019/188164.

The sensor 20 is configured by connecting the piezoresistive element 218 of the MEMS element 21A and the piezoresistive element 218 of the MEMS element 21B in series. A connection node 22 between the MEMS element 21A and the MEMS element 21B serves as an output end of the sensor signal S₁. The other end of the piezoresistive element 218 of the MEMS element 21A is connected to a power supply line, and the other end of the piezoresistive element 218 of the MEMS element 21B is connected to a ground line. A voltage (for example, 5 V) supplied to the power supply line is divided by a voltage dividing circuit configured by the piezoresistive element 218 of the MEMS element 21A and the piezoresistive element 218 of the MEMS element 21B. A voltage signal at a level corresponding to a resistance ratio between the piezoresistive element 218 of the MEMS element 21A and the piezoresistive element 218 of the MEMS element 21B is output from the output end of the sensor 20 as the sensor signal S₁. The signal level of the sensor signal S₁ is a level corresponding to the concentration of a specific component contained in the gas. Since the sensor 20 has the MEMS element 21B not containing the polymer 216, variation in the sensor signal S₁ due to factors other than a specific component contained in the gas, such as temperature and humidity, is curbed.

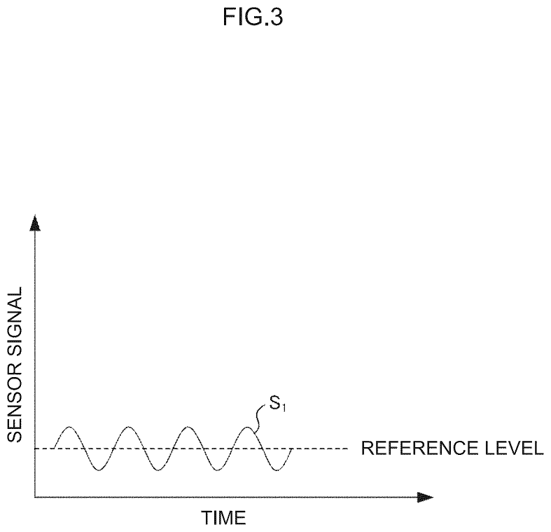

FIG. 3 is a signal waveform diagram showing an example of the sensor signal S₁. A constant level of the sensor signal S₁ according to the resistance ratio between the piezoresistive element 218 of the MEMS element 21A and the piezoresistive element 218 of the MEMS element 21B is set as a reference level (0 level), and the level changes according to the concentration of a specific component contained in a gas.

The output end of the sensor 20 is connected to an inverting input terminal of the differential amplifier circuit 30 and the control circuit 40. A non-inverting input terminal of the differential amplifier circuit 30 is connected to the voltage output circuit 50. The differential amplifier circuit 30 outputs an output signal S₃ obtained by amplifying a difference between the sensor signal S₁ input to the inverting input terminal and a reference voltage signal S₂ input to the non-inverting input terminal by a predetermined amplification factor. The reference voltage signal S₂ is a DC voltage signal having a constant voltage level. The reference voltage signal S₂ may be input to the inverting input terminal, and the sensor signal S₁ may be input to the non-inverting input terminal.

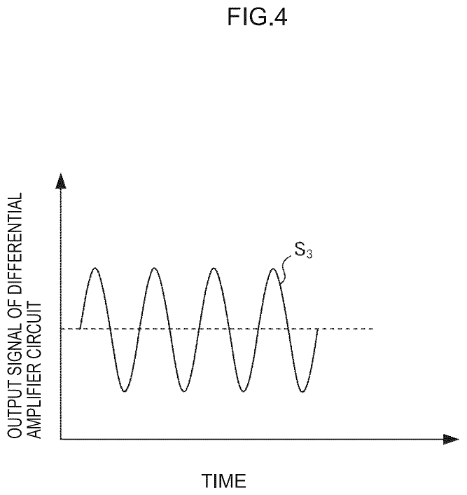

FIG. 4 is a signal waveform diagram showing an example of the output signal S₃ of the differential amplifier circuit 30. The output signal S₃ of the differential amplifier circuit 30 has a waveform obtained by amplifying the amplitude of the sensor signal S₁. The output signal S₃ of the differential amplifier circuit 30 is processed by a signal processing circuit (not shown).

The control circuit 40 includes a low-pass filter (LPF) 41, an analog-to-digital converter (ADC) 42, and a microcomputer 43. The sensor signal S₁ output from the sensor 20 is input to the low-pass filter 41. The low-pass filter 41 extracts a low-frequency component of the sensor signal S₁, and the high-frequency component of the sensor signal S₁ is removed by the low-pass filter 41. A change in the sensor signal S₁ according to a specific component included in the gas is included in the high-frequency component. Therefore, a change in the sensor signal S₁ according to a specific component contained in the gas is removed by the low-pass filter 41. The DC component of the sensor signal S₁ passes through the low-pass filter 41. That is, the low-pass filter 41 outputs a voltage signal at a level corresponding to the reference level of the sensor signal S₁. In the low-pass filter 41, a cutoff frequency may be set to extract a DC component of the sensor signal S₁.

The analog-to-digital converter 42 converts the output signal of the low-pass filter 41, which is an analog signal, into a digital signal. That is, a digital value corresponding to the reference level of the sensor signal S₁ is output from the analog-to-digital converter 42.

The microcomputer 43 performs a predetermined calculation on the digital value output from the analog-to-digital converter 42 to generate a control signal S₄ for setting a reference voltage signal S₂. Specifically, the microcomputer 43 generates the control signal S₄ such that a voltage signal at the same level as the reference level of the sensor signal S₁ indicated by the digital value output from the analog-to-digital converter 42 is output as the reference voltage signal S₂. The control signal S₄ is supplied to the voltage output circuit 50.

Since the control circuit 40 includes the low-pass filter 41, the analog-to-digital converter 42, and the microcomputer 43, the control circuit 40 realizes a function of increasing or decreasing a level of the reference voltage signal S₂ by an amount corresponding to the amount of change in the reference level of the sensor signal S₁.

The voltage output circuit 50 outputs a voltage signal at a level set by control signal S₄ supplied from microcomputer 43 as reference voltage signal S₂. That is, the voltage output circuit 50 outputs the reference voltage signal S₂ at the same level as the reference level of the sensor signal S₁. The reference voltage signal S₂ is input to the non-inverting input terminal of the differential amplifier circuit 30. The voltage output circuit 50 may include, for example, a three-terminal regulator of a variable output voltage type.

Hereinafter, an operation of the sensor signal processing device 10 will be described. The sensor signal S₁ output from the sensor 20 is input to the inverting input terminal of the differential amplifier circuit 30 and is input to the control circuit 40. As shown in FIG. 3, the sensor signal S₁ is a signal of which a level changes according to the concentration of a specific component contained in a gas with a constant level as a reference level (zero level). The reference level of the sensor signal S₁ is a DC component of the sensor signal S₁.

The change in the sensor signal S₁ according to the specific component contained in the gas is removed by the low-pass filter 41. The DC component of the sensor signal S₁ passes through the low-pass filter 41. That is, a voltage signal at a level corresponding to the reference level of the sensor signal S₁ is output from the low-pass filter 41. The voltage signal at the level corresponding to the reference level of the sensor signal S₁ output from the low-pass filter 41 is converted into a digital signal by the analog-to-digital converter 42 and supplied to the microcomputer 43. The microcomputer 43 generates the control signal S₄ such that a voltage signal at the same level as the reference level of sensor signal S₁ is output as the reference voltage signal S₂, and supplies the control signal S₄ to the voltage output circuit 50. The voltage output circuit 50 outputs the reference voltage signal S₂ at the same level as the reference level of sensor signal S₁ on the basis of the control signal S₄.

The differential amplifier circuit 30 outputs the output signal S₃ obtained by amplifying a difference between the sensor signal S₁ input to the inverting input terminal and the reference voltage signal S₂ input to the non-inverting input terminal by a predetermined amplification factor. Since the level of the reference voltage signal S₂ input to the non-inverting input terminal is the same as the reference level of the sensor signal S₁ input to the inverting input terminal, the reference level of the sensor signal S₁ is canceled. That is, out of the reference level component and the variation component corresponding to the specific component contained in the gas, included in the sensor signal S₁, only the latter is amplified in the differential amplifier circuit 30.

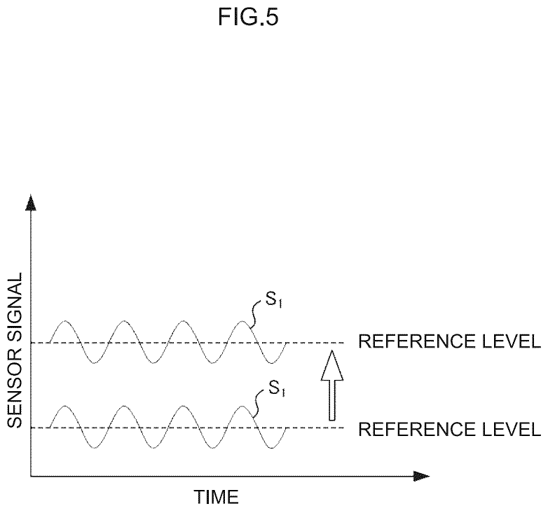

A resistance ratio between the piezoresistive element 218 of the MEMS element 21A and the piezoresistive element 218 of the MEMS element 21B is assumed to change due to aging or the like. In the sensor 20, in a case in which the resistance ratio changes, the reference level of the sensor signal S₁ changes as exemplified in FIG. 5. FIG. 5 shows a state in which the reference level of the sensor signal S₁ increases due to aging.

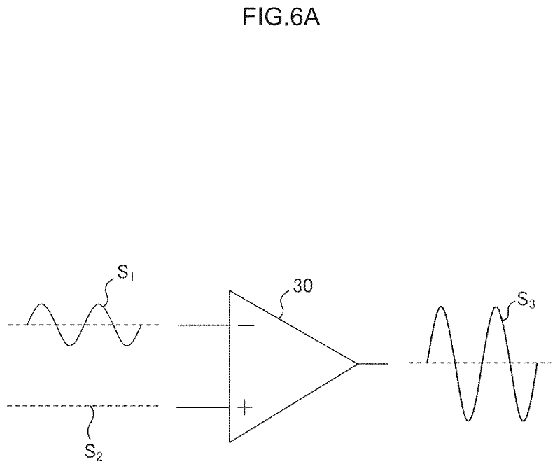

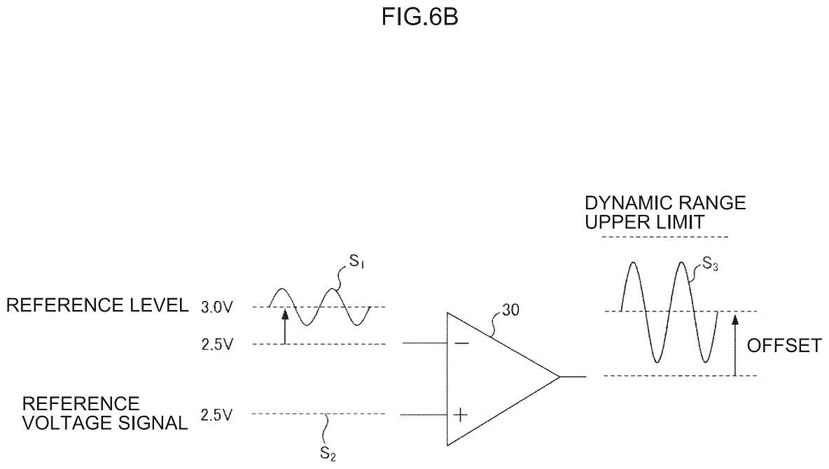

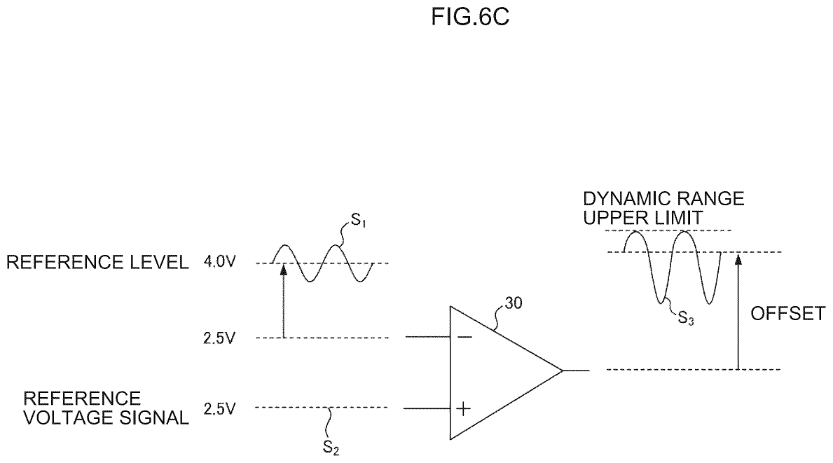

Here, FIGS. 6A, 6B, and 6C are diagrams showing examples of input and output waveforms of the differential amplifier circuit 30 in a case in which the level control of the reference voltage signal S₂ in the control circuit 40 is not performed. FIG. 6A shows a case in which the level (2.5 V) of the reference voltage signal S₂ input to the non-inverting input terminal is the same as the reference level (2.5 V) of the sensor signal S₁ input to the inverting input terminal. In this case, the reference level of the sensor signal S₁ is canceled, and out of the reference level component (DC component) and the variation component (AC component) corresponding to the specific component contained in the gas, included in the sensor signal S₁, only the latter is amplified by the differential amplifier circuit 30.

FIG. 6B shows a case in which the reference level of the sensor signal S₁ rises from 2.5 V to 3.0 V. The level of the reference voltage signal S₂ remains at 2.5 V. In this case, the reference level of the sensor signal S₁ is not completely canceled, and not only the variation component (AC component) but also the reference level component (DC component) of the sensor signal S₁ is amplified. As a result, the output signal S₃ is offset.

FIG. 6C shows a case in which the reference level of the sensor signal S₁ further increases to 4.0 V. The level of the reference voltage signal S₂ remains at 2.5 V. In a case in which a difference between the reference level of the sensor signal S₁ and the level of the reference voltage signal S₂ increases, an offset amount of the output signal S₃ increases. In a case in which the offset amount becomes excessive and the output signal S₃ approaches a dynamic range upper limit, distortion occurs in the output signal S₃.

According to the sensor signal processing device 10 according to the embodiment, the reference voltage signal S₂ at the same level as the reference level of the sensor signal S₁ is input to the differential amplifier circuit 30. In a case in which the reference level of the sensor signal S₁ changes due to aging of the sensor 20 or the like, the level of the reference voltage signal S₂ changes to follow the change. Therefore, even in a case in which the reference level of the sensor signal S₁ changes, the change is canceled and is not amplified in the differential amplifier circuit 30. That is, according to the sensor signal processing device 10, even in a case in which the reference level of the sensor signal S₁ changes, the reference voltage signal S₂ is controlled such that the output signal S₃ of the differential amplifier circuit 30 falls within the dynamic range.

According to the sensor signal processing device 10, since the output signal S₃ of the differential amplifier circuit 30 is not used in the control of the reference voltage signal S₂, it is possible to control the reference voltage signal S₂ without depending on an amplification factor of the differential amplifier circuit 30.

According to the sensor signal processing device 10 of the embodiment, since, out of the reference level component and the variation component corresponding to the specific component contained in the gas included in the sensor signal S₁, only the latter is extracted to generate the control signal S₄, the reference voltage signal S₂ can be controlled even during the operation of the sensor 20.

As described above, according to the sensor signal processing device 10 of the embodiment, the variation in the reference level of the sensor signal S₁ can be canceled without depending on an amplification factor of the differential amplifier circuit 30 and without providing a calibration mode.

In the above description, an aspect has been exemplified in which control is performed such that a voltage signal at the same level as the reference level of the sensor signal S₁ is output as the reference voltage signal S₂. However, the disclosed technology is not limited to this aspect. The reference level of the sensor signal S₁ and the level of the reference voltage signal S₂ need not coincide with each other as long as the reference voltage signal S₂ can be controlled such that the output signal S₃ of the differential amplifier circuit 30 falls within the dynamic range.

In the above description, the aspect of controlling the level of the reference voltage signal S₂ on the basis of the low-frequency component of the sensor signal S₁ extracted by the low-pass filter 41 has been exemplified. However, the disclosed technology is not limited to this aspect. For example, the sensor signal S₁ may be converted into a digital signal by the analog-to-digital converter 42, and the level of the reference voltage signal S₂ may be adjusted on the basis of an average value of sampling values of the digital signal. By setting a sampling period to a relatively long period, it is possible to extract a voltage signal at a level corresponding to the reference level of the sensor signal S₁. The average value of the sampling values may be a moving average value. According to this aspect, the low-pass filter 41 is unnecessary.

In the above description, the case in which the sensor 20 is a gas sensor has been exemplified, but the disclosed technology can be applied to any sensor in which the reference level of the sensor signal S₁ can vary due to aging or the like.

The following supplementary notes regarding the above embodiment will be disclosed.

### (Supplementary Note 1)

A sensor signal processing device including:
a differential amplifier circuit that outputs an output signal according to a difference between a sensor signal output from a sensor and a reference voltage signal; and
a control circuit that controls a level of the reference voltage signal on the basis of the sensor signal.

### (Supplementary Note 2)

The sensor signal processing device according to Supplementary Note 1, in which
the control circuit increases or decreases the level of the reference voltage signal by an amount corresponding to a change amount of a reference level of the sensor signal.

### (Supplementary Note 3)

The sensor signal processing device according to Supplementary Note 1 or 2, in which
the control circuit adjusts the level of the reference voltage signal on the basis of a low-frequency component of the sensor signal.

### (Supplementary Note 4)

The sensor signal processing device according to any one of Supplementary Notes 1 to 3, further including
a low-pass filter that extracts a low-frequency component of the sensor signal.

### (Supplementary Note 5)

The sensor signal processing device according to any one of Supplementary Notes 1 to 4, in which
the control circuit adjusts the level of the reference voltage signal on the basis of an average value of sampling values of the sensor signal.

### (Supplementary Note 6)

The sensor signal processing device according to any one of Supplementary Notes 1 to 5, in which
the differential amplifier circuit includes two input terminals,
the sensor signal is input to one of the input terminals, and
the reference voltage signal is input to the other of the input terminals.

### (Supplementary Note 7)

The sensor signal processing device according to any one of Supplementary Notes 1 to 6, further including
an analog-to-digital converter that converts the sensor signal into a digital signal.

### (Supplementary Note 8)

The sensor signal processing device according to any one of Supplementary Notes 1 to 7, further including
the sensor.

### (Supplementary Note 9)

The sensor signal processing device according to any one of Supplementary Notes 1 to 8, in which
the sensor includes a resistive element of which a resistance value changes according to a concentration of a gas containing a specific component, and outputs a signal at a level according to the resistance value of the resistive element as the sensor signal.

The disclosure of Japanese Patent Application No. 2022-194906 filed on Dec. 6, 2022 is incorporated herein by reference in its entirety. All documents, patent applications, and technical standards described in this specification are incorporated herein by reference to the same extent as if each document, patent application, and technical standard were specifically and individually indicated to be incorporated by reference.

1. A sensor signal processing device comprising:
a differential amplifier circuit that outputs an output signal according to a difference between a sensor signal output from a sensor and a reference voltage signal; and
a control circuit that controls a level of the reference voltage signal on the basis of the sensor signal.

2. The sensor signal processing device according to claim 1, wherein
the control circuit increases or decreases the level of the reference voltage signal by an amount corresponding to a change amount of a reference level of the sensor signal.

3. The sensor signal processing device according to claim 1, wherein
the control circuit adjusts the level of the reference voltage signal on the basis of a low-frequency component of the sensor signal.

4. The sensor signal processing device according to claim 3, further comprising
a low-pass filter that extracts a low-frequency component of the sensor signal.

5. The sensor signal processing device according to claim 1, wherein
the control circuit adjusts the level of the reference voltage signal on the basis of an average value of sampling values of the sensor signal.

6. The sensor signal processing device according to claim 1, wherein
the differential amplifier circuit includes two input terminals,
the sensor signal is input to one of the input terminals, and
the reference voltage signal is input to the other of the input terminals.

7. The sensor signal processing device according to claim 1, further comprising
an analog-to-digital converter that converts the sensor signal into a digital signal.

8. The sensor signal processing device according to claim 1, further comprising
the sensor.

9. The sensor signal processing device according to claim 8, wherein
the sensor includes a resistive element of which a resistance value changes according to a concentration of a gas containing a specific component, and outputs a signal at a level according to the resistance value of the resistive element as the sensor signal.

10. The sensor signal processing device according to claim 2, wherein
the control circuit adjusts the level of the reference voltage signal on the basis of a low-frequency component of the sensor signal.

11. The sensor signal processing device according to claim 2, wherein
the control circuit adjusts the level of the reference voltage signal on the basis of an average value of sampling values of the sensor signal.

12. The sensor signal processing device according to claim 2, wherein
the differential amplifier circuit includes two input terminals,
the sensor signal is input to one of the input terminals, and
the reference voltage signal is input to the other of the input terminals.

13. The sensor signal processing device according to claim 2, further comprising
an analog-to-digital converter that converts the sensor signal into a digital signal.

14. The sensor signal processing device according to claim 2, further comprising
the sensor.
